(19) United States
(12) Patent Application Publication
(10) Pub. No.: US 2025/0273557 A1
(43) Pub. Date: Aug. 28, 2025

(54) LASER DEBOND PROCESS FOR FABRICATION OF HIGH-DENSITY ORGANIC INTERPOSERS

(71) Applicant: Intel Corporation, Santa Clara, CA (US)

(72) Inventors: Thomas L. SOUNART, Chandler, AZ (US); Aleksandar ALEKSOV, Chandler, AZ (US); Shawna M. LIFF, Scottsdale, AZ (US); Johanna M. SWAN, Scottsdale, AZ (US); Veronica STRONG, Hillsboro, OR (US); Tushar TALUKDAR, Wilsonville, OR (US); Sarah ATANASOV, Beaverton, OR (US)

(21) Appl. No.: 18/584,932

(22) Filed: Feb. 22, 2024

(51) Int. Cl. H01L 23/498; H01L 21/48

(52) U.S. Cl. CPC H01L 23/49883; H01L 21/4842; H01L 21/486; H01L 23/49827

(57) ABSTRACT

Embodiments disclosed herein comprise a method for assembling an interposer. In an embodiment, the method comprises assembling a structure over a carrier substrate, where the structure is mechanically coupled to the carrier substrate by a debond film. In an embodiment, the structure comprises an organic dielectric layer, and the debond film comprises an inorganic layer. The method may further comprise ablating at least a portion of the debond film with a laser. In an embodiment, a wavelength of the laser is within an infrared range. The method may further comprise separating the carrier substrate from the structure.

### BACKGROUND

Advanced packaging process flows often employ temporary carriers for assembly processes. These carriers are typically glass wafers with an organic adhesive and release layer that is decomposed thermally or by UV laser absorption when the overlying substrate needs to be released from the carrier. However, such solutions have a high total thickness variation (TTV) (e.g., up to approximately 5 μm or larger). The glass wafers are also not compatible with many silicon wafer handling tools present within a fabrication facility.

Another approach for carrier solutions is to use a silicon carrier wafer. In such an embodiment, the bond between the wafer and the overlying interposer (or other structure) is not deactivated. Instead, the silicon wafer is thinned with a grinding process that can ultimately remove the entire silicon carrier wafer. This is an expensive process because carriers cannot be reused. Additionally, there is a risk of damage or degradation to the overlying structure during the recessing process. Another solution may include the use of a thermal release bonding film. However, the temperature limit for many interposer solutions is less than approximately 200° C. Thermal bond layers also have a high thickness without a high degree of uniformity (i.e., they may have a high TTV).

### BRIEF DESCRIPTION OF THE DRAWINGS

FIG. 1A is a cross-sectional illustration of a carrier with a debond film over the carrier, in accordance with an embodiment.

FIG. 1B is a cross-sectional illustration of a carrier with a multi-layer debond film, in accordance with an embodiment.

FIG. 1C is a cross-sectional illustration of a carrier with a multi-layer debond film, in accordance with an embodiment.

FIGS. 2A-2D are cross-sectional illustrations depicting a process for assembling an interposer on a carrier and releasing the carrier with a laser debond process, in accordance with an embodiment.

FIG. 3 is a process flow diagram of a process for debonding an interposer from a carrier with a laser process, in accordance with an embodiment.

FIGS. 4A-4F are cross-sectional illustrations depicting a process for assembling an interposer with dies that are bridged together by a routing layer and releasing the interposer from a carrier with a laser process, in accordance with an embodiment.

FIGS. 5A-5L are cross-sectional illustrations depicting a process for forming a zero-misaligned via over a carrier, and releasing the interposer from the carrier with a laser process, in accordance with an embodiment.

FIGS. 6A-6D are cross-sectional illustrations depicting a process for assembling an interposer with dies that are bridged together by a routing layer and releasing the interposer from a carrier with a laser process, in accordance with an embodiment.

FIGS. 7A-7B are cross-sectional illustrations depicting a process of forming an interposer with multiple layers of dies coupled to a carrier and releasing the carrier with a laser process, in accordance with an embodiment.

FIGS. 8A-8B are cross-sectional illustrations depicting a process of forming an interposer with conductive pillars and releasing the interposer from a carrier with a laser process, in accordance with an embodiment.

FIG. 9 is a schematic of a computing device built in accordance with an embodiment.

### EMBODIMENTS OF THE PRESENT DISCLOSURE

Described herein are electronic systems, and more particularly, organic interposer devices that are fabricated through the use of a laser debonding process, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

Future scaling to higher density routing layers and interconnects, has led to an interest in silicon based carriers. Compared to glass-based carriers, silicon carriers offer a lower total thickness variation (TTV), better geometric stability, and compatibility with all silicon wafer handling tools and processes. Further, elimination of the organic adhesive and release layers allows for improved TTV at the point of the adhesive. Improved release layer design can also provide improved thermal and/or mechanical stability that leads to opportunities for high density 2.5D and 3D integration.

More generally, embodiments disclosed herein include the use of a release layer (also referred to herein as a debond film or a debond layer), that is sensitive to infrared (IR) radiation. In some embodiments, the debond film absorbs the IR radiation so that the debond film is ablated. This allows for the overlying interposer (or other structure) to be released. Silicon wafers are transparent to IR radiation, so the laser can be directed to the debond film through the thickness of the silicon carrier wafer. IR radiation may refer to radiation with a wavelength between approximately 800 nm and approximately 1.0 mm. In a particular embodiment, the IR radiation may have a wavelength between approximately 1.0 μm and approximately 10 μm, or between approximately 1.0 μm and approximately 20 μm. As used herein, “approximately” may refer to a range of values that are within ten percent of the stated value. For example, approximately 10 μm may refer to a range between 9 μm and 11 μm.

In an embodiment, the debond film may have a material composition suitable for deposition with a well-controlled deposition process, such as physical vapor deposition (PVD), atomic layer deposition (ALD), or chemical vapor deposition (CVD). These deposition processes may enable the formation of thin and low TTV materials. Between the low TTV of the silicon carrier and the low TTV of the debond film, a total TTV of the carrier system may be approximately 5 μm or less, or approximately 1 μm or less. In an embodiment, the debond film may have a thickness that is up to approximately 5 nm, up to approximately 10 nm, up to approximately 20 nm, up to approximately 30 nm, up to approximately 50 nm, or up to approximately 100 nm. The debond film may have a single layer composition, or a multi-layer composition (as will be described in greater detail below). In the case of multi-layer approaches, the total thickness of all layers of the debond film may be up to approximately 500 nm, up to approximately 600 nm, or up to approximately 1,000 nm. Though, thicker debond films may also be used in some embodiments.

The debond film and silicon carrier wafer combination have benefits in addition to improved TTV, improved thermal stability, and improved mechanical stability. For example, costs of assembly can be reduced through the reuse of the silicon carrier wafers. In some instances, a cleaning process (e.g., an etching process) can be used to remove any residual material. A new debond film can then be deposited over the cleaned carrier substrate.

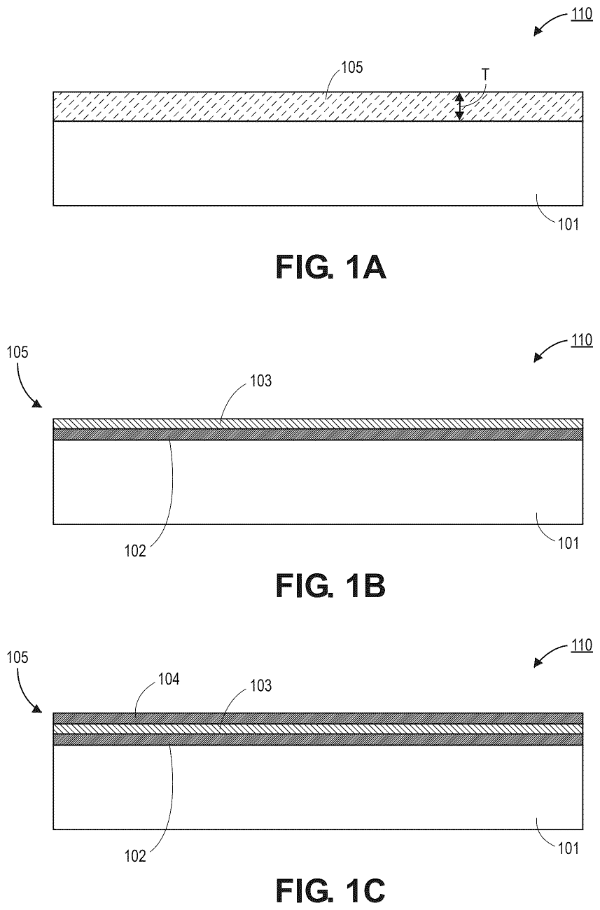

Referring now to FIG. 1A, a cross-sectional illustration of a carrier 110 is shown, in accordance with an embodiment. In an embodiment, the carrier 110 comprises a substrate 101 and a debond film 105 over the substrate 101. In an embodiment, the substrate 101 may have a wafer form factor. For example, a diameter of the substrate 101 may be approximately 200 mm, approximately 300 mm, or approximately 450 mm. Though, other wafer sizes may also be used in some embodiments.

In an embodiment, the substrate 101 comprises a silicon substrate. The silicon substrate 101 may be a high purity silicon material with a low dopant concentration (or substantially no dopants). In an embodiment, the silicon substrate 101 may have a thermal oxide (not shown). The silicon substrate 101 may have any suitable crystal orientation. For example, substrate 101 may have a (100) crystal orientation, a (111) crystal orientation, or a (110) crystal orientation. In an embodiment, the substrate 101 is a material that is substantially transparent to IR radiation. For example, IR radiation between approximately 1 μm and approximately 20 μm may pass through the substrate 101 without significant absorption of the IR radiation. Silicon substrates 101 satisfy this parameter in many embodiments. While silicon may be one example of a suitable substrate 101, other materials that are at least partially transparent to IR radiation may also be used in some embodiments. For example, the substrate 101 may also comprise germanium, sapphire, or silicon and carbon (e.g., silicon carbide), or glass. As used herein, “partially transparent to IR radiation” may refer to a material that absorbs up to 75% of the IR radiation that passes through the material, absorbs up to 25% of the IR radiation that passes through the material, absorbs up to 10% of the IR radiation that passes through the material, absorbs up to 5% of the IR radiation that passes through the material, or absorbs up to 1% of the IR radiation that passes through the material.

In an embodiment, the debond film 105 is provided over a top surface of the substrate 101. The debond film 105 may be a material that is configured to absorb the IR radiation that passes through the substrate 101 during a debonding process. In an embodiment, the debond film 105 may have a thickness T. The thickness T may be up to approximately 500 nm, up to approximately 100 nm, up to approximately 50 nm, up to approximately 20 nm, or up to approximately 10 nm. Though, larger thicknesses T may also be used in some embodiments. For example, the thickness T may be up to approximately 5 μm or greater in some embodiments.

In an embodiment, the debond film 105 may be deposited with a blanket deposition process. That is, the debond film 105 may be substantially uniform (with respect to thickness and material composition) across the surface of the substrate 101. For example, deposition processes may comprise PVD, CVD, ALD, and/or the like. In an embodiment, the combination of the debond film 105 and the substrate 101 may have a TTV that is approximately 5 μm or less, or approximately 1 μm or less.

In an embodiment, the debond film 105 may comprise a material (or materials) that are tuned for absorbing the IR radiation. In an embodiment, the debond film 105 may comprise an inorganic material. For example, the debond film 105 may comprise a thin metal layer or multiple metal layers (e.g., aluminum (Al), tungsten (W), copper (Cu), tantalum (Ta), titanium (Ti), molybdenum, (Mo), manganese (Mn), hafnium (Hf), chromium (Cr), niobium (Nb), zirconium (Zr), palladium (Pd), platinum (Pt), gold (Au), silver (Ag), ruthenium (Ru), tantalum nitride (TaN), titanium nitride (TiN), niobium nitride (NbN), chromium nitride (CrN), hafnium nitride (HfN), zirconium nitride (ZrN)). In some embodiments, the debond film 105 may additionally or alternatively include one or more layers of dielectric materials (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅), hafnium oxide (HfO₂), or zirconium oxide (ZrO₂)), which may be used to buffer laser ablation and thermal energy, or control thin film interference or adhesion. Thus, in some embodiments, the release layer(s) may be made of one or more materials that include elements such as aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), ruthenium (Ru), silicon (Si), oxygen (O), nitrogen (N), hydrogen (H), and carbon (C), including, without limitation, any of the materials referenced above.

In the illustrated embodiment of FIG. 1A, the debond film 105 is shown as a single layer. However, it is to be appreciated that the debond film 105 may comprise two or more layers. For example, the multiple layers may comprise absorption layers, transmission layers, and reflection layers. The reflection layers may reflect IR radiation back to the absorption layers through transmission layers in order to improve ablation of the debond film 105 during the laser release process. Examples of such multi-layer debond films 105 are shown in FIGS. 1B and 1C.

Referring now to FIG. 1B, a cross-sectional illustration of a carrier 110 is shown, in accordance with an additional embodiment. In an embodiment, the carrier 110 in FIG. 1B may be similar to the carrier 110 in FIG. 1A, with the exception of the construction of the debond film 105. For example, the debond film 105 may comprise a multi-layer stack, such as one with a first layer 102 and a second layer 103 over the first layer. In an embodiment, the first layer 102 may be an inorganic material that is configured to absorb the IR radiation from a laser release process. The second layer 103 may be a layer configured to reflect a significant portion of the IR radiation. The reflected IR radiation is directed back to the first layer 102, in order to improve the absorption (and ablation) of the first layer 102. As such, the release process is made more efficient.

In an embodiment, the first layer 102 may comprise a metallic layer (e.g., aluminum (Al), tungsten (W), copper (Cu), tantalum (Ta), titanium (Ti), molybdenum, (Mo), manganese (Mn), hafnium (Hf), chromium (Cr), niobium (Nb), zirconium (Zr), palladium (Pd), platinum (Pt), gold (Au), silver (Ag), ruthenium (Ru), tantalum nitride (TaN), titanium nitride (TiN), niobium nitride (NbN), chromium nitride (CrN), hafnium nitride (HfN), or zirconium nitride (ZrN)). In an embodiment, the second layer 103 may comprise a dielectric, such as silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅), hafnium oxide (HfO₂), or zirconium oxide (ZrO₂)).

In an embodiment, the thickness of the first layer 102 may be different than a thickness of the second layer 103. In an embodiment, the first layer 102 may be thinner than the second layer 103. Making the first layer 102 thinner allows for easier ablation of the first layer 102.

Referring now to FIG. 1C, a cross-sectional illustration of a carrier 110 is shown, in accordance with an additional embodiment. In an embodiment, the carrier 110 in FIG. 1C is similar to the carrier 110 in FIG. 1B, with the exception of the debond film 105. Instead of two layers 102 and 103, a set of three layers (i.e., a first layer 102, a second layer 103, and a third layer 104) are provided. In an embodiment, the first layer 102 may be an inorganic material that is configured to absorb the IR radiation from a laser release process. The second layer 103 may be a layer configured to reflect a significant portion of the IR radiation and transmit a significant portion of the IR radiation. The reflected IR radiation is directed back to the first layer 102. The third layer 104 may be configured to reflect a significant portion of the IR radiation back to the first layer 102, in order to improve the absorption (and ablation) of the first layer 102. As such, the release process is made more efficient. In an embodiment, the third layer 104 may also be configured to prevent transmission of a significant portion of the IR radiation. While examples of a two layer debond film 105 (FIG. 1B) and a three layer debond film 105 (FIG. 1C) are shown, it is to be appreciated that the debond film 105 can comprise any number of layers, including layers below the first layer 102 and/or above the third layer 104 in FIG. 1C.

In one embodiment, the first layer 102 and the fourth layer 104 may be similar to each other (as indicated by the shading). Though, in other embodiments, the first layer 102 may be different than the fourth layer 104. In an embodiment, the compositions, thicknesses, order, etc. of the various layers may be chosen in order to optimize the ablation of at least a portion of the debond film 105, and reduce or prevent transmission through the debond film 105. For example, multiple layers of the debond film 105 may be used to buffer laser ablation and thermal energy, control thin film interference between layers, and/or to improve adhesion between the carrier 110 and a subsequently added structure (not shown in FIGS. 1A-1C).

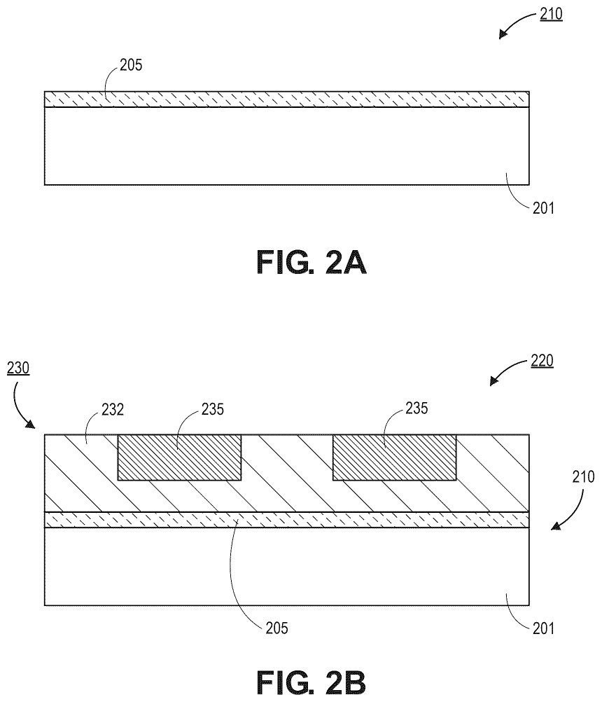

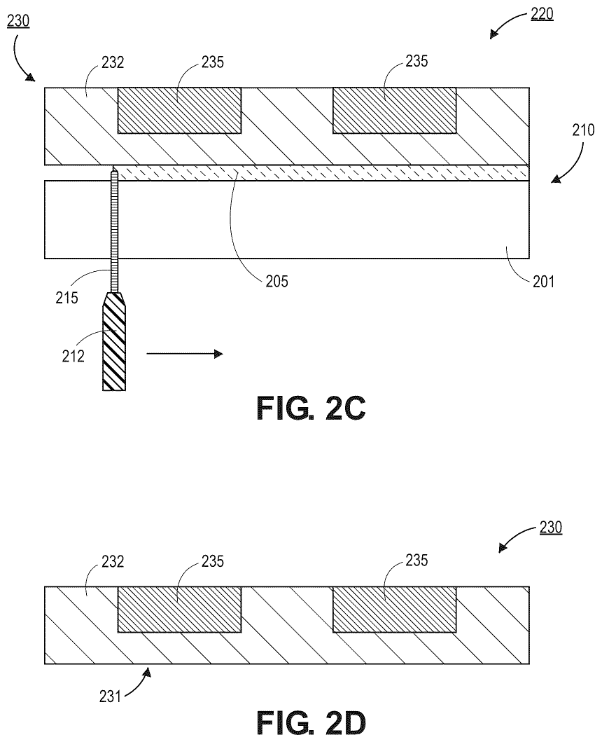

Referring now to FIGS. 2A-2D, a series of cross-sectional illustrations depicting a process for assembling an electronic device is shown, in accordance with an embodiment. In the embodiments shown in FIGS. 2A-2D, the carrier 210 is shown with a debond film 205 that is similar to the debond film 105 in FIG. 1A. Though, it is to be appreciated that the debond film 205 may be similar to any of the debond films described in greater detail herein. That is, the debond film 205 may include any number of layers. Further, any debond films described herein may include multiple layer configurations such as those described with respect to FIGS. 1B and 1C.

Referring now to FIG. 2A, a cross-sectional illustration of a carrier 210 is shown, in accordance with an embodiment. In an embodiment, the carrier 210 may comprise a substrate 201 and a debond film 205. The substrate 201 may comprise a silicon substrate. The debond film 205 may comprise an inorganic debond film 205 similar to any of the debond films described in greater detail herein. More generally, the carrier 210 may be similar to any of the carriers 110 described in greater detail herein.

In an embodiment, the carrier 210 has a wafer form factor. The wafer form factor allows for a plurality of devices to be fabricated in parallel with others. However, for simplicity, a single electronic device is shown. As will be appreciated, after debonding, the multiple electronic devices may be singulated before integration into a larger structure or system.

Referring now to FIG. 2B, a cross-sectional illustration of an assembly 220 is shown, in accordance with an embodiment. The assembly 220 may comprise the carrier 210 and an overlying device 230. The device 230 may be fabricated up from the carrier 210 in some embodiments. The device 230 may sometimes be referred to as an interposer or the like. In an embodiment, the device 230 may comprise an organic substrate 232. The organic substrate 232 may comprise organic buildup film, an epoxy, and/or the like. While shown as a monolithic structure in FIG. 2B, it is to be appreciated that the organic substrate 232 may comprise a plurality of laminated layers in some embodiments. Electrical routing (not shown) may also be provided within the organic substrate 232 in some embodiment.

In an embodiment, one or more dies 235 may be integrated into the device 230. The dies 235 may be embedded within the organic substrate 232, provided over the organic substrate 232, or provided at any other suitable position. In an embodiment, dies 235 may comprise any type of die, such as a processor (e.g., a central processing unit (CPU), a graphics processing unit (GPU), an XPU), an application specific integrated circuit (ASIC), a field programmable gate array (FPGA), a communications die, a memory die, or the like. Additionally, when two or more dies 235 are included in the device 230, the dies 235 may be the same type of die, or the dies 235 may be different types of dies.

Referring now to FIG. 2C, a cross-sectional illustration of the assembly 220 during a laser release process is shown, in accordance with an embodiment. As shown, a laser 212 is scanned across the backside surface of the substrate 201 of the carrier 210. IR radiation 215 passes through the substrate 201 and is absorbed by the debond film 205. The absorption raises a temperature of the debond film 205 (or a portion of the debond film 205), and results in the ablation of at least a portion of the debond film 205. As the laser 212 is scanned across the assembly 220, the mechanical connection between the device 230 and the carrier 210 is removed so that the device 230 can be lifted off of the carrier 210.

Referring now to FIG. 2D, a cross-sectional illustration of the device 230 after removal from the carrier 210 is shown, in accordance with an embodiment. In an embodiment, the removal of the debond film 205 may leave some layers and/or residue on a surface 231 of the organic substrate 232. The surface 231 may be cleaned with a cleaning or etching process or the like. In other embodiments, the debond film 205 may be designed such that at least a portion of the debond film 205 is used as a layer on the organic substrate 232. For example, a portion of the debond film 205 may persist onto the surface 231 of the organic substrate 232, and the portion of the debond film 205 may be used as a solder resist or the like. As used herein, the remaining portion of the debond film 205 left of the organic substrate 232 may be a complete layer or complete layers (e.g., an inorganic dielectric layer). Providing an inorganic dielectric layer over the metallic layer that will be ablated allows for overlying copper metal traces and the like to be plated on the inorganic dielectric as opposed to the underlying metal layer. Throughout the application, the debonding processes may all comprise a residual portion (e.g., one or more organic dielectric layers) left on the device that is being manufactured. These layers may be maintained (e.g., for use as a solder mask) or removed, depending on the needs of the device.

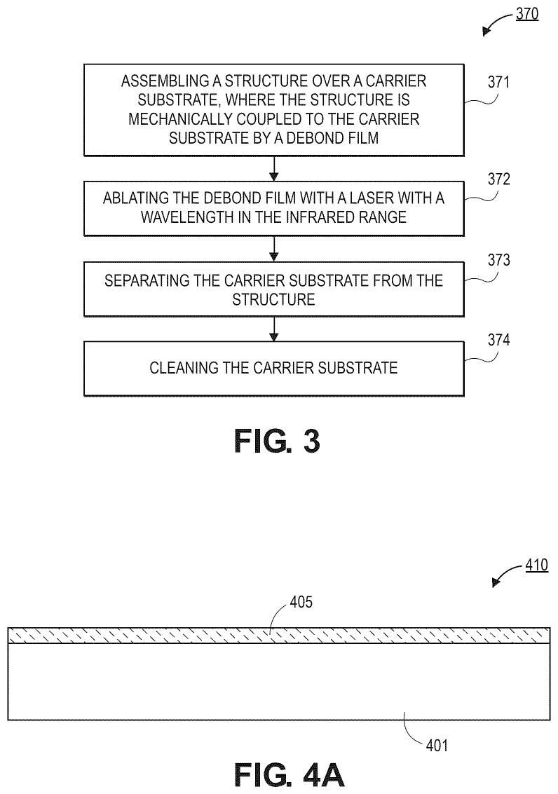

Referring now to FIG. 3, a process flow diagram of a process 370 for forming a device with a carrier substrate and an IR laser release process is shown, in accordance with an embodiment. In an embodiment, the process 370 may be similar to the process shown above with respect to FIGS. 2A-2D. However, processes similar to process 370 may be used in order to fabricate devices similar to any of the embodiments described in greater detail herein.

In an embodiment, the process 370 may begin with operation 371, which comprises assembling a structure over a carrier substrate. In an embodiment, the structure is mechanically coupled to the carrier substrate by a debond film. The structure may be an organic structure such as an interposer or the like. The structure may comprise any number of dies, components, electrical routing and/or the like. In an embodiment, the carrier substrate and the debond film may be similar to any of the carrier substrates and/or debond films described in greater detail herein. For example, the carrier substrate may be a silicon wafer, and the debond film may be an inorganic layer that absorbs IR radiation.

In an embodiment, the process 370 may continue with operation 372, which comprises ablating the debond film with a laser with a wavelength in the IR range. The debond film may be completely ablated, or a portion of the debond film may be ablated. In an embodiment, the IR laser is scanned across the backside of the carrier substrate. The IR radiation passes through the substrate and is absorbed by the debond film. The increased temperature of the debond film leads to ablation of the material.

In an embodiment, the process 370 may continue with operation 373, which comprises separating the carrier substrate from the structure. In an embodiment, the structure may be able to be lifted off of the carrier substrate after the laser release process. In some embodiments, the structure may be cleaned following removal from the carrier substrate. Though, in other embodiments residual portions of the debond film on the structure may be used as a solder resist or the like.

In an embodiment, the process 370 may continue with operation 374, which comprises cleaning the carrier substrate. The carrier substrate may be cleaned with an etching process or the like. The cleaning process may remove residual portions of the debond film. As a result, a clean substrate (e.g., silicon wafer) is provided that can be used in subsequent processes. For example, a new debond film may be added to the substrate in a subsequent processing operation.

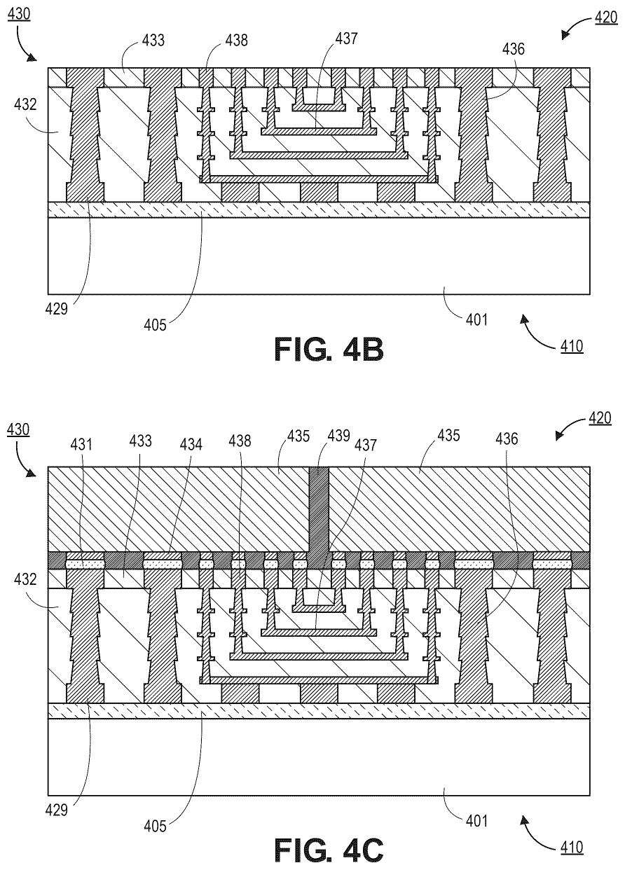

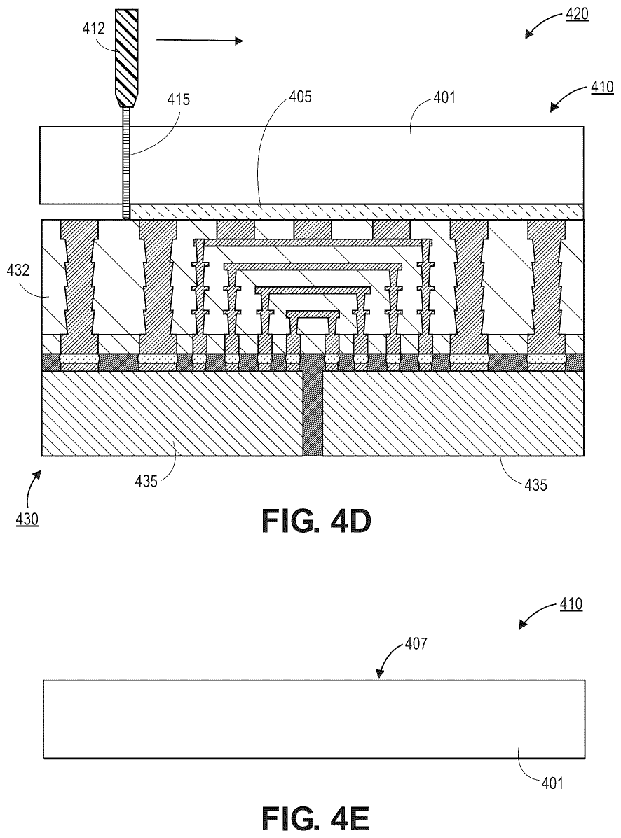

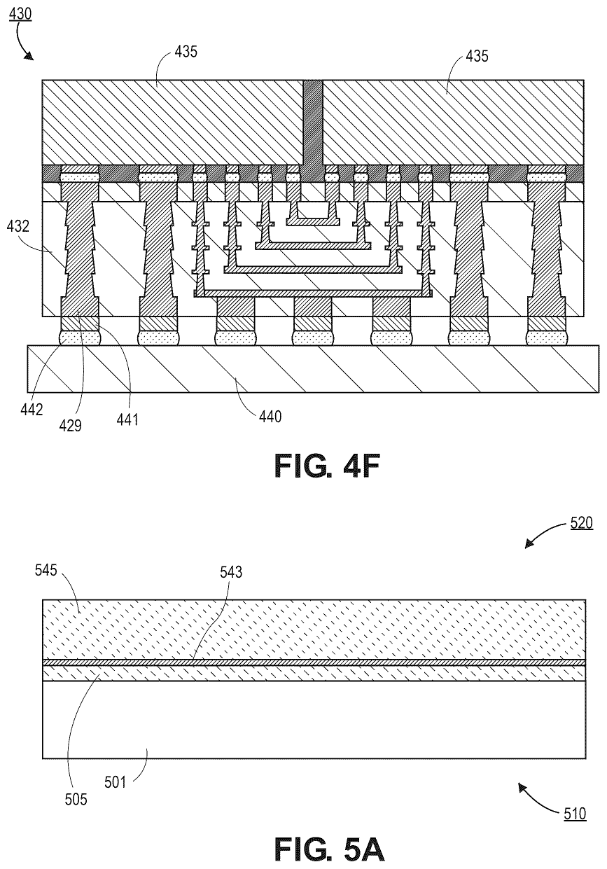

Referring now to FIGS. 4A-4F, a series of cross-sectional illustrations depicting a process for forming a device 430 with a carrier substrate and IR laser debond process is shown, in accordance with an embodiment. In an embodiment, the device 430 is formed with an interposer first process, followed by die attachment.

Referring now to FIG. 4A, a cross-sectional illustration of a carrier 410 is shown, in accordance with an embodiment. In an embodiment, the carrier 410 may comprise a substrate 401 and a debond film 405 over the substrate 401. The substrate 401 may be a silicon wafer or the like. The substrate 401 may be similar to any of the carrier substrate structures described in greater detail herein. In an embodiment, the debond film 405 may be similar to any of the debond films described in greater detail herein. For example, the debond film 405 may comprise an inorganic material (or materials) suitable for absorbing IR radiation.

Referring now to FIG. 4B, a cross-sectional illustration of an assembly 420 is shown, in accordance with an embodiment. In an embodiment, the assembly 420 may comprise a device 430 is that is built on the carrier 410, assembled on the carrier 410, attached to the carrier 410, and/or the like. In an embodiment, the device 430 may comprise an organic interposer 432, such as a plurality of laminated buildup layers. In an embodiment, electrical routing (e.g., pads 429, traces 437, vias 436, etc.) may be provided within the interposer 432. In an embodiment, a solder resist 433 or other organic layer may be provided around pads 428 at a top of the interposer 432.

Referring now to FIG. 4C, a cross-sectional illustration of the assembly 420 after dies 435 are added is shown, in accordance with an embodiment. In an embodiment, the dies 435 may be similar to any of the dies described in greater detail herein. The dies 435 may be connected to the pads 428 through a solder 431 and pads 434. Though, any suitable interconnect architecture, such as a first level interconnect (FLI), solution may be used to connect the dies 435 to the interposer 432. As shown in FIG. 4C, traces 437 within the interposer 432 may be used to electrically and communicatively couple the dies 435 together. Though, in other embodiments the dies 435 remain isolated (electrically) from each other. In an embodiment, a mold layer 439, such as an epoxy, is provided around the dies 435.

Referring now to FIG. 4D, a cross-sectional illustration of the assembly 420 after the assembly is flipped, and a laser ablation process is initiated is shown, in accordance with an embodiment. In an embodiment, the laser ablation process may include scanning a laser 412 across the backside of the substrate 401. Laser IR radiation 415 passes through the substrate 401 and is absorbed by the debond film 405. At least a portion of the debond film 405 is ablated, and the device 430 can be removed from the carrier 410.

Referring now to FIG. 4E, a cross-sectional illustration of the carrier 410 after device 430 is released is shown, in accordance with an embodiment. In an embodiment, the top surface 407 of the substrate 401 may be bare, due to the ablation process. In other embodiments, any residual material on the top surface 407 from the debond film 405 may be removed with an etching process or the like. The resulting substrate 401 can then be processed to add a new debond film 405, and the carrier 410 can be reused.

Referring now to FIG. 4F, a cross-sectional illustration of the device 430 after the interposer 432 is attached to a board 440 is shown, in accordance with an embodiment. In an embodiment, the board 440 may be a motherboard, a printed circuit board (PCB), or the like. The board 440 may be coupled to the interposer 432 with any suitable second level interconnect (SLI) structure. For example, solder balls 442 coupled to bumps 441 on the pads 438 can be used in some embodiments. Other embodiments may comprise the use of pins, sockets, or the like.

In an embodiment, the device 430 may be singulated before being attached to the board 440. That is, the device 430 may be part of a wafer level assembly system. After the carrier 410 is removed, the interposer may be singulated in order to provide individual devices 430. Each individual device 430 may then be mounted to a board 440.

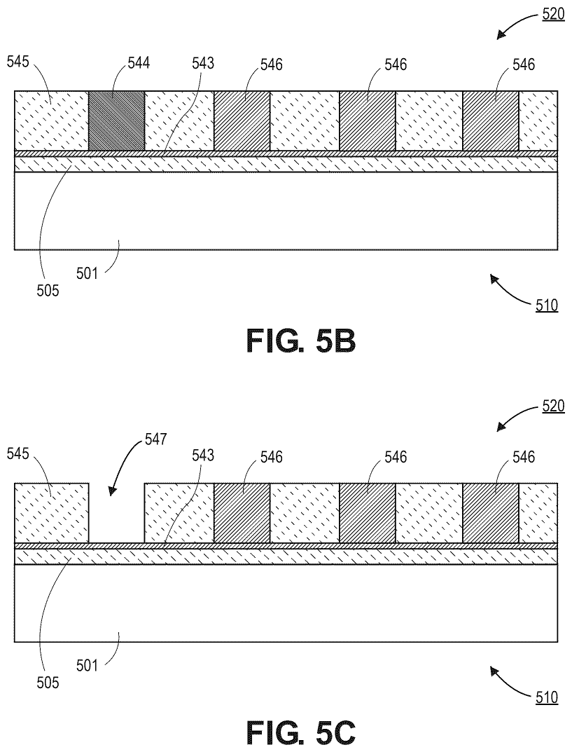

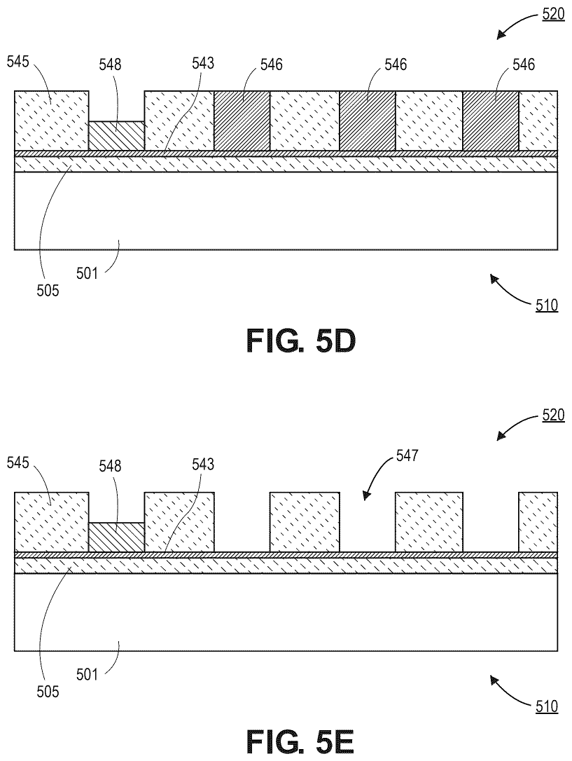

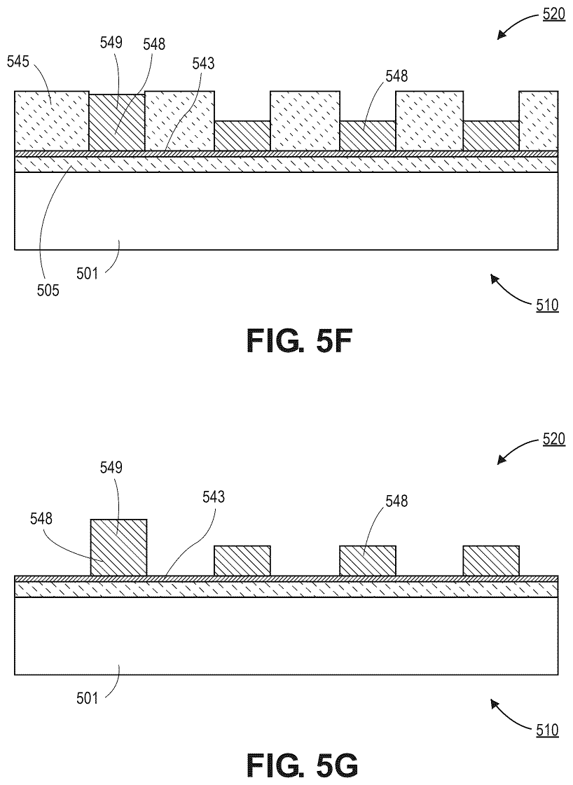

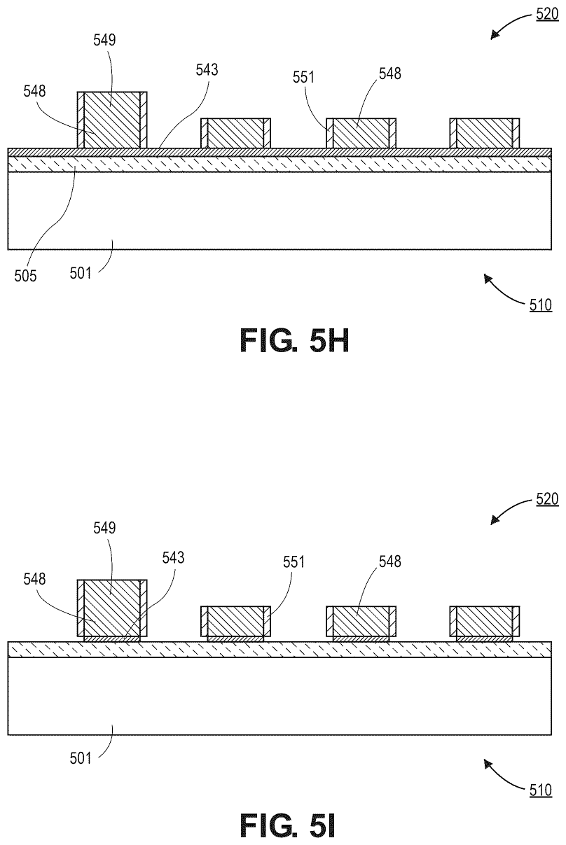

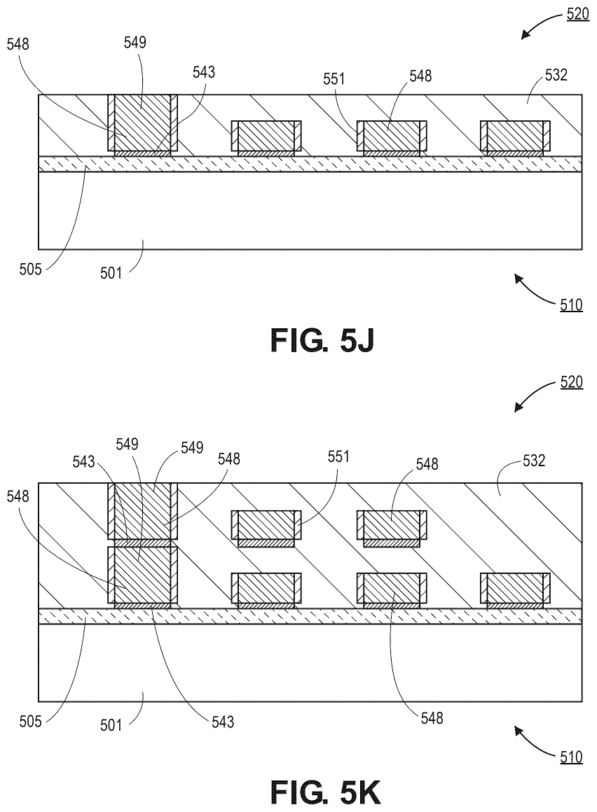

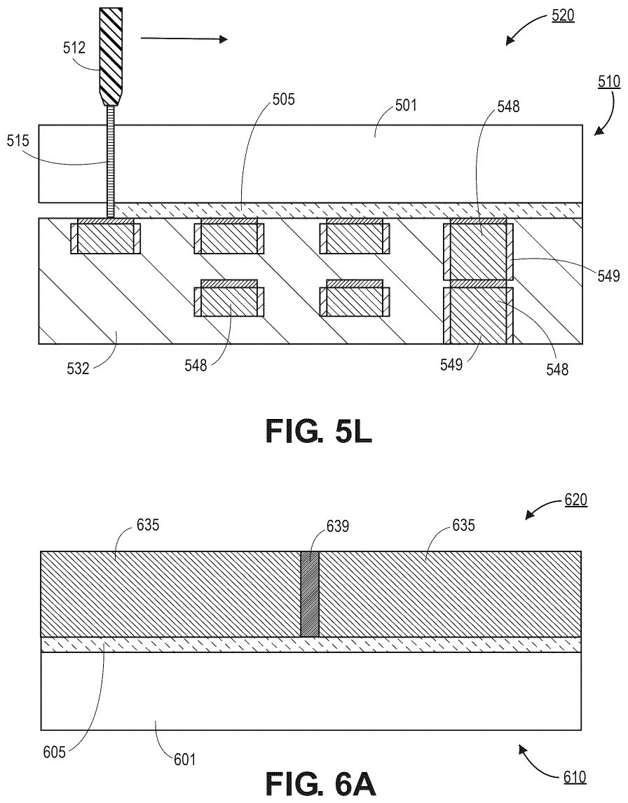

Referring now to FIGS. 5A-5L, a series of cross-sectional illustrations depicting a process of forming an interposer with zero-misaligned vias is shown, in accordance with an embodiment. As will be appreciated from the process flow, the vias described herein will have essentially no misalignment due to the manufacturing process. Such a structure may be fabricated in conjunction with a carrier that includes an IR debond film, such as those described in greater detail herein.

Referring now to FIG. 5A, a cross-sectional illustration of an assembly 520 is shown, in accordance with an embodiment. The assembly 520 may comprise a carrier 510. The carrier 510 may be similar to any of the carriers described in greater detail herein. For example, the carrier 510 may comprise a silicon wafer substrate 501 with an inorganic debond film 505. In an embodiment, a seed layer 543 may be provided over the debond film 505. The seed layer 543 may comprise an electrically conductive material suitable for use in plating processes. In an embodiment, a resist layer 545 is provided over the seed layer 543. The resist layer 545 may be any suitable photoresist material.

Referring now to FIG. 5B, a cross-sectional illustration of the assembly 520 after the resist layer 545 is patterned is shown, in accordance with an embodiment. In an embodiment, the resist layer 545 may be patterned with a grayscale mask in order to have a first region 544 that is fully exposed and other regions 546 that are not fully exposed. For example, the mask (not shown) used for exposure may have a first region where light is not attenuated (i.e., to form regions 544), a second region where light is attenuated in a controlled fashion to attenuate a given percentage of the light to provide partial exposure (i.e., to form regions 546), and a third region where no light passes in order to not alter the resist layer 545 (i.e., the remaining portions of the resist layer 545). While a positive-tone resist is shown in FIGS. 5A-5L, similar processes may also be implemented using a negative tone resist.

Referring now to FIG. 5C, a cross-sectional illustration of the assembly 520 after the first region 544 is developed is shown, in accordance with an embodiment. The developing process forms an opening 547 that exposes the underlying seed layer 543. The other regions 546 are shown as being unaffected by the developing process. However, some embodiments may include a recess in the regions 546. However, the underlying seed layer 543 is not exposed. As such, subsequent plating will only occur in the opening 547.

Referring now to FIG. 5D, a cross-sectional illustration of the assembly 520 after an interconnect element 548 is provided in the opening 547 is shown, in accordance with an embodiment. The interconnect element 548 may refer to a structure such as a pad, a trace, a plane, or the like. In an embodiment, the interconnect element 548 may be plated up from the seed layer 543 using a plating process, such as an electroplating process. In an embodiment, plating is stopped before the top of the interconnect element 548 reaches the top of the resist layer 545.

Referring now to FIG. 5E, a cross-sectional illustration of the assembly 520 after the regions 546 are developed to form openings 547 is shown, in accordance with an embodiment. The openings 547 expose the underlying seed layer 543 to enable plating in the openings 547.

Referring now to FIG. 5F, a cross-sectional illustration of the assembly 520 after a second plating operation is shown, in accordance with an embodiment. As shown, interconnect elements 548 may be formed in the openings 547. Additionally, a via 549 may plate up from the top of the first interconnect element 548. Since the via 549 is plated up and confined by the same hole in the resist layer 545 used to form the underlying interconnect element 548, there will be no misalignment between the via 549 and the underlying interconnect element 548.

Referring now to FIG. 5G, a cross-sectional illustration of the assembly 520 after the resist layer 545 is stripped is shown, in accordance with an embodiment. The resist layer 545 may be stripped with an ashing process, or any other suitable etching process that is selective to the resist layer 545 over other materials in the assembly 520.

Referring now to FIG. 5H, a cross-sectional illustration of the assembly 520 after a spacer formation process is shown, in accordance with an embodiment. In an embodiment, the spacer formation process may include depositing a conformal spacer layer over all surfaces. An asymmetric etch can then be used in order to remove the spacer layer from horizontal surfaces. As such, spacers 551 may remain along sidewalls of the interconnect element 548 and vias 549. The spacers 551 may be dielectric material, such as an oxide, a nitride, or the like.

Referring now to FIG. 5I, a cross-sectional illustration of the assembly 520 after the seed layer 543 is etched is shown, in accordance with an embodiment. In an embodiment, the seed layer 543 may be etched with a wet etching process. The etching of the seed layer 543 electrically isolates the interconnect element 548 from each other.

Referring now to FIG. 5J, a cross-sectional illustration of the assembly 520 after a buildup layer 532 is deposited over and around the interconnect element 548 and via 549 is shown, in accordance with an embodiment. In an embodiment, the buildup layer 532 may be an organic dielectric material, such as a buildup film, an epoxy, a mold material, and/or the like. In an embodiment a top surface of the buildup layer 532 may be recessed to be substantially coplanar with a top surface of the via 549.

Referring now to FIG. 5K, a cross-sectional illustration of the assembly 520 after operations 5A-5J are repeated to form a second layer over the first layer is shown, in accordance with an embodiment. Interconnect element 548 may be provided above and below the via 549. In some embodiments, a seed layer 543 may be provided between the via 549 and the overlying interconnect element 548. In the case where vias are not desired, interconnect element 548 may be separated from interconnect element 548 of another layer by portions of the buildup layer 532. The process can be repeated any number of times to provide a desired number of electrical routing layers for the assembly 520.

Referring now to FIG. 5L, a cross-sectional illustration of the assembly 520 during a laser ablation process is shown, in accordance with an embodiment. In an embodiment, the laser ablation process may include scanning a laser 512 across the backside of the substrate 501. Laser IR radiation 515 passes through the substrate 501 and is absorbed by the debond film 505. At least a portion of the debond film 505 is ablated, and the buildup layer 532 (with the embedded electrical routing) can be removed from the carrier 510. In an embodiment, the carrier 510 can be cleaned and reused, similar to other embodiments described in greater detail herein.

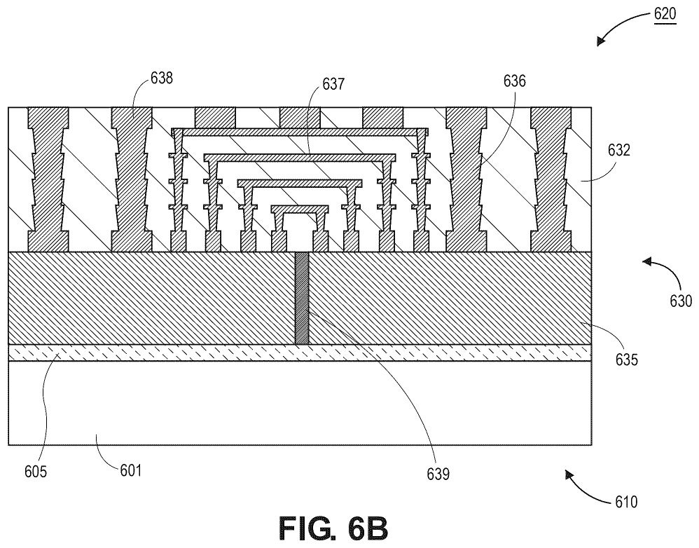

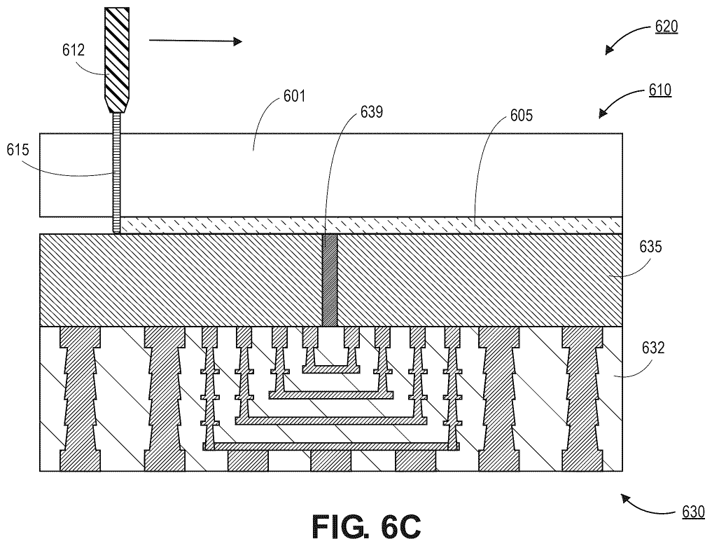

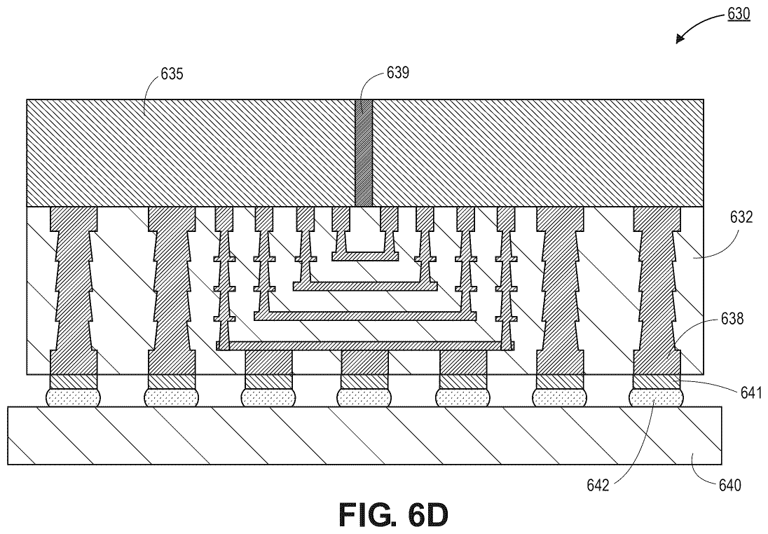

Referring now to FIGS. 6A-6D, a series of cross-sectional illustrations depicting a die-first assembly process using a carrier with a debond film compatible with IR laser ablation is shown, in accordance with an embodiment. That is to say, embodiments are not limited to the processing flow being die-first or die-last.

Referring now to FIG. 6A, a cross-sectional illustration of an assembly 620 is shown, in accordance with an embodiment. In an embodiment, the assembly 620 comprises a carrier 610. The carrier 610 may be similar to any of the carriers described in greater detail herein. For example, the carrier 610 may comprise a substrate 601 (e.g., a silicon substrate 601), and a debond film 605 (e.g., an inorganic debond film 605).

In an embodiment, one or more dies 635 may be attached to the debond film 605. The dies 635 may be attached to the debond film 605 with an adhesive (not shown), such as a die attach film (DAF) or the like. In other embodiments, the debond film 605 may sufficiently adhere to the dies 635 without the need of another adhesive. In some embodiments, a mold layer 639, an epoxy, or the like may be provided around the dies 635. The surface of the mold layer 639 may be recessed back so that surfaces of the dies 635 are exposed.

Referring now to FIG. 6B, a cross-sectional illustration of the assembly 620 after an interposer 632 is attached to the dies 635 to form a device 630 is shown, in accordance with an embodiment. In an embodiment, the interposer 632 may comprise buildup film or the like. Electrically conductive features (e.g., pads 638, vias 636, traces 637, etc.) may be embedded within the interposer 632. The interposer 632 may be built up over the dies 635 in a layer-by-layer process. Or a completed interposer may be attached over the dies 635. In an embodiment, conductive features within the interposer 632 may be used to electrically and communicatively couple together two of the dies 635. For example, traces 637 may provide electrical coupling between dies 635.

Referring now to FIG. 6C, a cross-sectional illustration of the assembly 620 during a laser release process is shown, in accordance with an embodiment. In an embodiment, the laser ablation process may include scanning a laser 612 across the backside of the substrate 601. Laser IR radiation 615 passes through the substrate 601 and is absorbed by the debond film 605. At least a portion of the debond film 605 is ablated, and the device 630 can be removed from the carrier 610. In an embodiment, the carrier 610 can be cleaned and reused, similar to other embodiments described in greater detail herein.

Referring now to FIG. 6D, a cross-sectional illustration of the assembly 620 after the device 630 is coupled to a board 640 is shown, in accordance with an embodiment. In an embodiment, the board 640 may be a motherboard, a PCB, or the like. The board 640 may be coupled to the interposer 632 with any suitable SLI structure. For example, solder balls 642 coupled to bumps 641 on the pads 638 can be used in some embodiments. Other embodiments may comprise the use of pins, sockets, or the like. In a particular embodiment, the bumps 641 may comprise a part of a redistribution layer (RDL) that is provided below the interposer 632. The RDL may comprise the bumps and a solder mask (not shown). In some embodiments, the solder mask may be part of the debond film 605 that remains attached to the interposer 632 after the debonding process.

In an embodiment, the device 630 may be singulated before being attached to the board 640. That is, the device 630 may be part of a wafer level assembly system. After the carrier 610 is removed, the interposer may be singulated in order to provide individual devices 630. Each individual device 630 may then be mounted to a board 640.

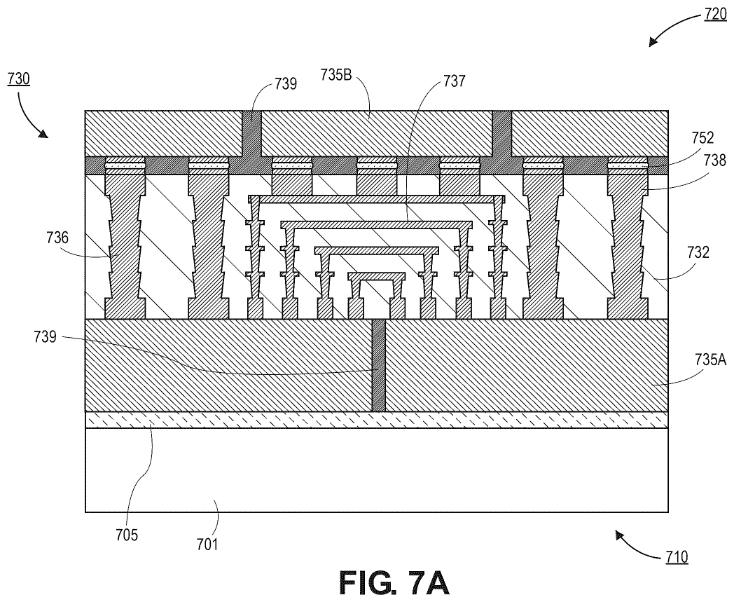

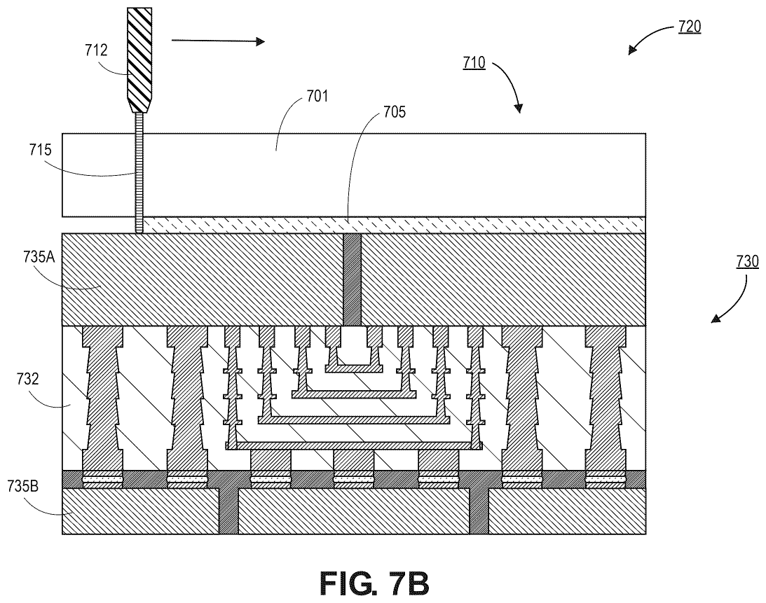

Referring now to FIGS. 7A and 7B, a pair of cross-sectional illustrations depicting a multi-level die structure fabricated on a carrier is shown, in accordance with an embodiment. Particularly, the TTV benefits of silicon carriers with an inorganic debond film allow for improved control of integration. This allows for more complex integrations where dies are provided in multiple levels of the device.

Referring now to FIG. 7A, a cross-sectional illustration of an assembly 720 is shown, in accordance with an embodiment. In an embodiment, the assembly 720 comprises a carrier 710. The carrier 710 may be similar to any of the carriers described in greater detail herein. For example, the carrier 710 may comprise a substrate 701 (e.g., a silicon substrate 701) and a debond film 705 (e.g., an inorganic debond film 705).

In an embodiment, a device 730 may be fabricated on the carrier 710. The device 730 may comprise multiple die levels. For example, dies 735A may be provided in a first level of the device 730. The dies 735A may be embedded in a mold layer 739 or the like. An interposer 732 with embedded electrical components and features (e.g., vias 736, pads 738, traces 737, etc.) may be provided over the first level of dies 735A. In an embodiment, a second level of dies 735B may be provided over a surface of the interposer 732 opposite from the first level of dies 735A. The second level of dies 735B may be coupled to pads 738 by solder 752 or the like. The second level of dies 735B may also be embedded in a mold layer 739.

Referring now to FIG. 7B, a cross-sectional illustration of the assembly 720 during a laser release process is shown, in accordance with an embodiment. In an embodiment, the laser ablation process may include scanning a laser 712 across the backside of the substrate 701. Laser IR radiation 715 passes through the substrate 701 and is absorbed by the debond film 705. At least a portion of the debond film 705 is ablated, and the device 730 can be removed from the carrier 710. In an embodiment, the carrier 710 can be cleaned and reused, similar to other embodiments described in greater detail herein. The released device 730 may be singulated (when a wafer-level assembly is used) and attached to a board or the like (not shown).

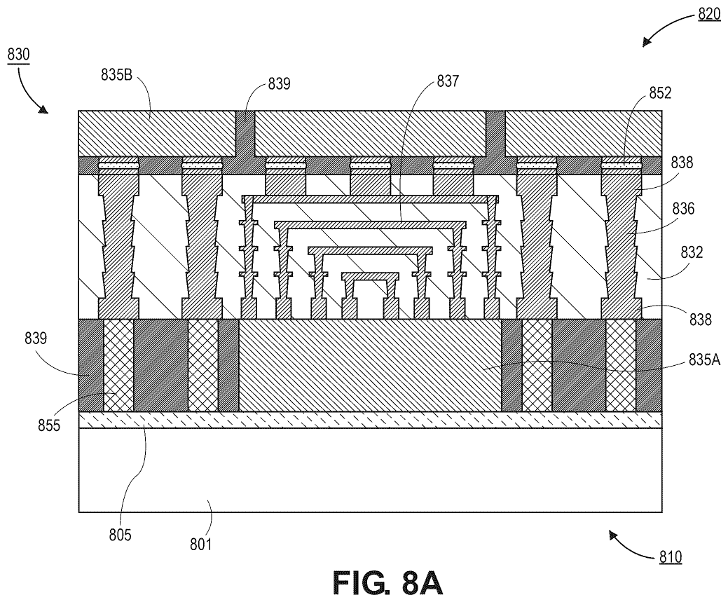

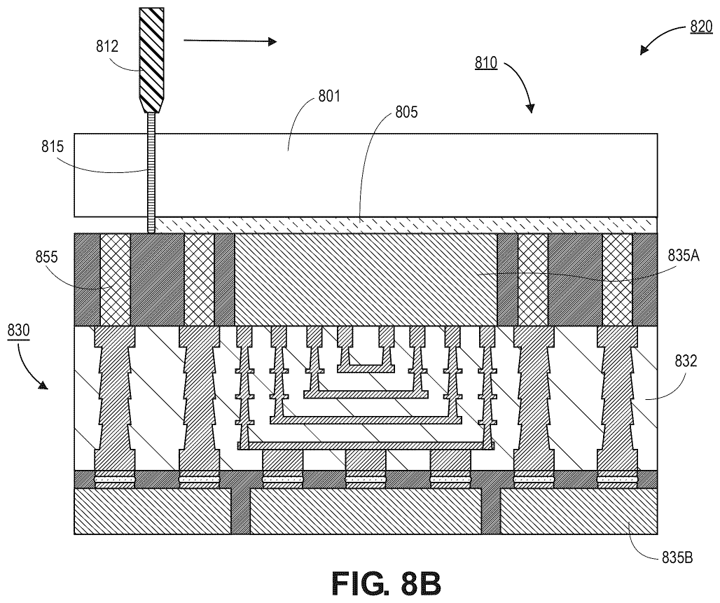

Referring now to FIGS. 8A and 8B, a pair of cross-sectional illustrations depicting a multi-level die structure fabricated on a carrier is shown, in accordance with an embodiment. Particularly, the TTV benefits of silicon carriers with an inorganic debond film allow for improved control of integration. This allows for more complex integrations where dies are provided in multiple levels of the device.

Referring now to FIG. 8A, a cross-sectional illustration of an assembly 820 is shown, in accordance with an embodiment. In an embodiment, the assembly 820 comprises a carrier 810. The carrier 810 may be similar to any of the carriers described in greater detail herein. For example, the carrier 810 may comprise a substrate 801 (e.g., a silicon substrate 801) and a debond film 805 (e.g., an inorganic debond film 805).

In an embodiment, a device 830 may be fabricated on the carrier 810. The device 830 may comprise multiple die levels. For example, a die 835A may be provided in a first level of the device 830. The die 835A may be embedded in a mold layer 839 or the like. In an embodiment, electrically conductive pillars 855 may also be provided through a thickness of the mold layer 839 adjacent to the die 835A. An interposer 832 with embedded electrical components and features (e.g., vias 836, pads 838, traces 837, etc.) may be provided over the first level of dies 835A. In an embodiment, a second level of dies 835B may be provided over a surface of the interposer 832 opposite from the first level of dies 835A. The second level of dies 835B may be coupled to pads 838 by solder 852 or the like. The second level of dies 835B may also be embedded in a mold layer 839.

Referring now to FIG. 8B, a cross-sectional illustration of the assembly 820 during a laser release process is shown, in accordance with an embodiment. In an embodiment, the laser ablation process may include scanning a laser 812 across the backside of the substrate 801. Laser IR radiation 815 passes through the substrate 801 and is absorbed by the debond film 805. At least a portion of the debond film 805 is ablated, and the device 830 can be removed from the carrier 810. In an embodiment, the carrier 810 can be cleaned and reused, similar to other embodiments described in greater detail herein. The released device 830 may be singulated (when a wafer-level assembly is used) and attached to a board or the like (not shown).

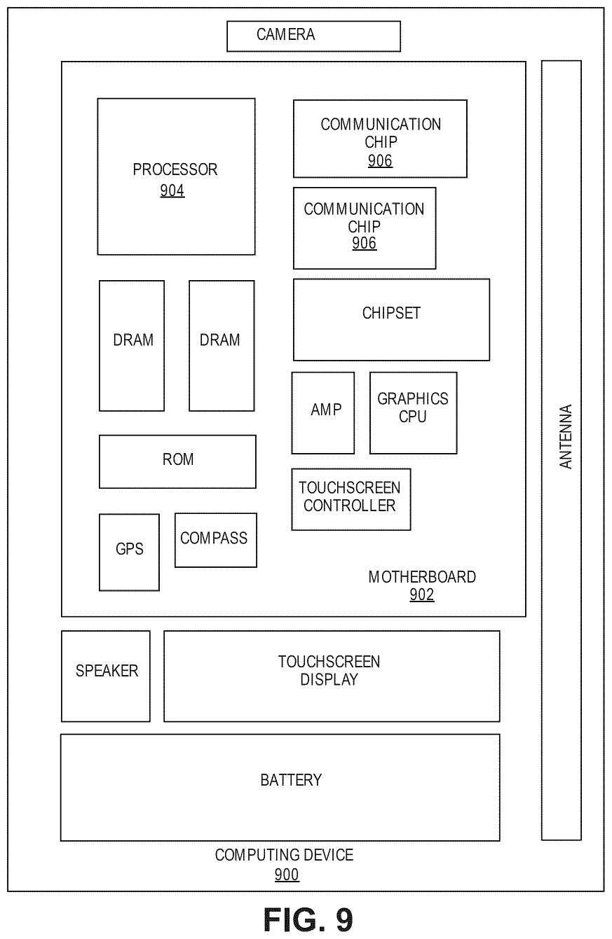

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that is fabricated through the use of a silicon carrier wafer with a debond film that is deactivated with an IR laser, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that is fabricated through the use of a silicon carrier wafer with a debond film that is deactivated with an IR laser, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a method of assembling an interposer, comprising: assembling a structure over a carrier substrate, wherein the structure is mechanically coupled to the carrier substrate by a debond film, wherein the structure comprises an organic dielectric layer, and wherein the debond film comprises an inorganic layer; ablating at least a portion of the debond film with a laser, wherein a wavelength of the laser is within an infrared range; and separating the carrier substrate from the structure.

Example 2: the method of Example 1, wherein the carrier substrate comprises a silicon wafer, and wherein the laser passes through a thickness of the silicon wafer to reach the debond film.

Example 3: the method of Example 1 or Example 2, wherein the structure comprises: a die embedded in the organic dielectric layer.

Example 4: the method of Example 3, wherein the structure further comprises: a second die above the die.

Example 5: the method of Examples 1-4, wherein the structure comprises, a zero-misaligned via.

Example 6: the method of Examples 1-5, wherein the structure comprises a pillar through at least a portion of a thickness of the organic dielectric layer.

Example 7: the method of Examples 1-6, wherein the structure comprises a redistribution layer, and wherein the redistribution layer comprises a solder mask that is originally part of the debond film.

Example 8: the method of Examples 1-7, wherein the debond film comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

Example 9: the method of Examples 1-8, wherein the debond film comprises a metallic layer and an inorganic dielectric layer directly on the metallic layer.

Example 10: a carrier substrate, comprising: a substrate, wherein the substrate comprises silicon; a debond layer over the substrate, wherein the debond layer comprises: a metallic layer on the substrate; and an inorganic dielectric layer over the metallic layer.

Example 11: the carrier substrate of Example 10, wherein the substrate is a wafer with at least a 200 mm diameter.

Example 12: the carrier substrate of Example 10 or Example 11, wherein the metallic layer comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

Example 13: the carrier substrate of Examples 10-12, wherein the dielectric layer comprises one or more of silicon, oxygen, nitrogen, carbon, aluminum, titanium, hafnium, zirconium, or tantalum.

Example 14: the carrier substrate of Examples 10-13, wherein the debond layer has a thickness up to 200 nm.

Example 15: the carrier substrate of Examples 10-14, wherein the substrate comprises an oxide layer over the silicon.

Example 16: the carrier substrate of Examples 10-15, wherein the silicon has a (100) crystal orientation, a (110) crystal orientation, or a (111) crystal orientation.

Example 17: a method of forming an electronic device, comprising: assembling an electronic package on a carrier substrate, wherein the electronic package is mechanically coupled to the carrier substrate by an inorganic debond film; debonding the electronic package from the carrier substrate by applying an infrared laser to the debond film to ablate at least a portion of the debond film; and attaching the electronic package to a board.

Example 18: the method of Example 17, wherein assembling the electronic package on the carrier substrate is a wafer-level assembly process.

Example 19: the method of Example 17 or Example 18, wherein the debond film comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

Example 20: the method of Examples 17-19, wherein the electronic device is part of a personal computer, a server, a mobile device, a tablet, or an automobile.

What is claimed is:

1. A method of assembling an interposer, comprising:
assembling a structure over a carrier substrate, wherein the structure is mechanically coupled to the carrier substrate by a debond film, wherein the structure comprises an organic dielectric layer, and wherein the debond film comprises an inorganic layer;
ablating at least a portion of the debond film with a laser, wherein a wavelength of the laser is within an infrared range; and
separating the carrier substrate from the structure.

2. The method of claim 1, wherein the carrier substrate comprises a silicon wafer, and wherein the laser passes through a thickness of the silicon wafer to reach the debond film.

3. The method of claim 1, wherein the structure comprises:
a die embedded in the organic dielectric layer.

4. The method of claim 3, wherein the structure further comprises:
a second die above the die.

5. The method of claim 1, wherein the structure comprises a zero-misaligned via.

6. The method of claim 1, wherein the structure comprises a pillar through at least a portion of a thickness of the organic dielectric layer.

7. The method of claim 1, wherein the structure comprises a redistribution layer, and wherein the redistribution layer comprises a solder mask that was part of the debond film.

8. The method of claim 1, wherein the debond film comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

9. The method of claim 1, wherein the debond film comprises a metallic layer and an inorganic dielectric layer directly on the metallic layer.

10. A carrier substrate, comprising:
a substrate, wherein the substrate comprises silicon;
a debond layer over the substrate, wherein the debond layer comprises:
a metallic layer on the substrate; and
an inorganic dielectric layer over the metallic layer.

11. The carrier substrate of claim 10, wherein the substrate is a wafer with at least a 200 mm diameter.

12. The carrier substrate of claim 10, wherein the metallic layer comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

13. The carrier substrate of claim 10, wherein the dielectric layer comprises one or more of silicon, oxygen, nitrogen, carbon, aluminum, titanium, hafnium, zirconium, or tantalum.

14. The carrier substrate of claim 10, wherein the debond layer has a thickness up to 200 nm.

15. The carrier substrate of claim 10, wherein the substrate comprises an oxide layer over the silicon.

16. The carrier substrate of claim 10, wherein the silicon has a (100) crystal orientation, a (110) crystal orientation, or a (111) crystal orientation.

17. A method of forming an electronic device, comprising:
assembling an electronic package on a carrier substrate, wherein the electronic package is mechanically coupled to the carrier substrate by an inorganic debond film;
debonding the electronic package from the carrier substrate by applying an infrared laser to the debond film to ablate at least a portion of the debond film; and
attaching the electronic package to a board.

18. The method of claim 17, wherein assembling the electronic package on the carrier substrate is a wafer-level assembly process.

19. The method of claim 17, wherein the debond film comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

20. The method of claim 17, wherein the electronic device is part of a personal computer, a server, a mobile device, a tablet, or an automobile.
